(19) United States
(12) Patent Application Publication
(10) Pub. No.: US 2025/0093387 A1
(43) Pub. Date: Mar. 20, 2025

(54) WAFER TEST SYSTEM

(71) Applicant: XINGR TECHNOLOGIES (ZHEJIANG) LIMITED, YIWU CITY (CN)

(72) Inventors: CHOON LEONG LOU, SINGAPORE (SG); HO YEH CHEN, ZHUBEI CITY (TW)

(21) Appl. No.: 18/621,964

(22) Filed: Mar. 29, 2024

(30) Foreign Application Priority Data
Sep. 15, 2023 (CN) 202311197186.X
Dec. 29, 2023 (CN) 202311863903.8

(51) Int. Cl. G01R 1/16; G01R 1/04; G01R 31/28

(52) U.S. Cl. CPC G01R 1/16; G01R 1/0416; G01R 31/2831

(57) ABSTRACT

A wafer test system is provided. The wafer test system includes a wafer test cassette, a carrier, and a test equipment. The wafer test cassette includes a first magnetic member. The carrier includes a second magnetic member. The wafer test cassette is fixed on the carrier through magnetic attraction generated between the first magnetic member and the second magnetic member. The test equipment includes a tester and a test cabinet. The test cabinet has a plurality of test spaces used to accommodate the wafer test cassettes and the carriers, and the tester is electrically connected to the wafer test cassette.

### CROSS-REFERENCE TO RELATED PATENT APPLICATION

This application claims the benefit of priorities to China Patent Application Nos. 202311197186.X, filed on Sep. 15, 2023, and 202311863903.8, filed on Dec. 29, 2023, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a wafer test system, and more particularly to a wafer test system with a magnetic attraction structure for fixing a wafer test cassette.

### BACKGROUND OF THE DISCLOSURE

When an integrated circuit is designed for a wafer, the wafer is subjected to a burn-in test and an electrical test. Conventionally, for the burn-in test and a reliability test, each wafer is tested individually using a tester and a probe card. Each wafer is placed on a carrier and electrically contacted by the probes of the probe card to perform the test. Therefore, when the amount of wafers increases, more testers and probe cards are required, causing the test process to be time-consuming and increasing equipment costs.

In the conventional technology, in order to improve the efficiency of the burn-in test, a composite test unit system has been developed to allow the burn-in test on several wafers to be simultaneously performed. Such a system includes multiple test units for the wafers to be respectively configured therein. Further, each test unit includes at least one chuck configured to fix the wafer, and wafer is connected to the tester for the burn-in test or the electrical test.

For another thing, a wafer test cassette has been developed recently, in which the probe card and the wafer are pre-positioned and configured in the wafer test cassette, and the wafer test cassette is directly and electrically connected to the tester. In addition, the wafer test cassette is disposed in the test unit for the burn-in test or the electrical test. Conventionally, the upper housing and the lower housing of the wafer test cassette are combined by means of engagement or vacuum. Adoption of the engagement means for the combination of the upper housing and the lower housing may have limited fixation effect, and may cause problems with uneven force application and defamation.

Therefore, how to improve the effectiveness of the test system through structural design improvement, to overcome the above issues has become one of the important issues to be addressed in the related field.

### SUMMARY OF THE DISCLOSURE

In response to the above-referenced technical inadequacies, the present disclosure provides a test system with a magnetic attraction fixing structure, and the test system includes a wafer test cassette and a test equipment. The wafer test cassette includes a first magnetic member and at least one first electrical contact. The test equipment includes a tester and at least one test cabinet. The test cabinet has a plurality of test spaces and a plurality of second electrical contacts. A plurality of carriers each including a second magnetic member, are correspondingly arranged in test positions of the test spaces. The test space is used to accommodate the wafer test cassette. The second electrical contact of the test cabinet is configured to be electrically connected to the first electrical contact of the wafer test cassette, so that the tester is electrically connected to the wafer test cassette. The wafer test cassette is fixed on the carrier through magnetic attraction generated between the first magnetic member and the second magnetic member.

In one of the possible or preferred embodiments, the tester is electrically connected to the wafer test cassette at the same time, before, or after the magnetic attraction is generated.

In one of the possible or preferred embodiments, the carrier includes a magnetic barrier assembly configured to reduce or eliminate the magnetic attraction.

In one of the possible or preferred embodiments, the wafer test cassette has an extension, and the first electrical contact is arranged on the extension.

In one of the possible or preferred embodiments, the test cabinet further includes a slide assembly connected to the carrier, and the slide assembly is configured to drive the carrier to move toward an interior or an exterior of the test space.

In one of the possible or preferred embodiments, the carrier is a slide assembly correspondingly disposed on two sides of a bottom of the wafer test cassette and configured to support the wafer test cassette.

In one of the possible or preferred embodiments, the wafer test cassette has at least one first positioning structure, the carrier has at least one second positioning structure corresponding to the at least one first positioning structure, and the at least one second positioning structure is configured to be engaged to the at least one first positioning structure.

In one of the possible or preferred embodiments, the wafer test cassette includes a first housing and a second housing that are tightly coupled to each other.

In order to solve the above-mentioned problems, another one of the technical aspects adopted by the present disclosure is to provide a test system, which includes a wafer test cassette and a test equipment. The wafer test cassette includes a first magnetic member and at least one first electrical contact. The test equipment includes a tester and at least one test cabinet. The test cabinet includes a plurality of test spaces and a plurality of second electrical contacts. The test space is used to accommodate the wafer test cassette, and the test space is defined by a top plate, a bottom plate, and a side wall. A second magnetic member is disposed in the test space, the second magnetic member is disposed on the bottom plate or the side wall, and the wafer test cassette is fixed in the test space through magnetic attraction generated between the first magnetic member and the second magnetic member. The second electrical contact of the test cabinet is configured to be electrical connected to the first electrical contact, so that the wafer test cassette is electrical connected to the tester

In one of the possible or preferred embodiments, the wafer test cassette has at least one first positioning structure, at least one of the top plate, the bottom plate, and the side wall has at least one second positioning structure corresponding to the at least one first positioning structure, and the at least one second positioning structure is configured to be engaged to the at least one first positioning structure.

In one of the possible or preferred embodiments, the first electrical contact of the wafer test cassette is connected to the second electrical contact through the magnetic attraction.

Therefore, one of the beneficial effects of the present disclosure is that the test system provided by the present disclosure can effectively improve efficiency of a wafer test process. In addition, the test equipment is connected to the wafer test cassette through a magnetic structure, so that a test environment can be effectively controlled.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a test system according to one embodiment of the present disclosure;

FIG. 2 is a schematic view of a test cabinet of the embodiment shown in FIG. 1;

FIG. 3 is a schematic view of a wafer test cassette of the embodiment shown in FIG. 1;

FIG. 4 is a schematic view of the wafer test cassette according to one embodiment of the present disclosure;

FIG. 5 is another schematic view of the wafer test cassette according to one embodiment of the present disclosure;

FIG. 6 is a schematic view of a test system according to one embodiment of the present disclosure; and

FIG. 7 is a schematic view showing a relationship between the wafer test cassette and a test space according to one embodiment of the present disclosure.

Reference numeral: SYS1 to SYS 2, test system; 1A to 1E, wafer test cassette; 11, first housing; 11P, first positioning structure; 11F, first protruding structure; 111, first magnetic member; 112, probe card; 1121, probe; 118, first electrical contact; 12, second housing; 12E, extension; 12F, second protruding structure; 12P, extension; 121, third magnetic member; SB, carrier; SB-P, second magnetic member; SB-B, magnetic barrier assembly; SB-F, second positioning structure; SEP, second electrical contact; 13, wafer; 131, pad; 21, top plate; 22, side wall; 23, bottom plate; TE1 and TE2, test equipment; TE11 and TE21, tester; TE12 and TE22, test cabinet; TS, test space; TS1 to TS25, test space.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Embodiments

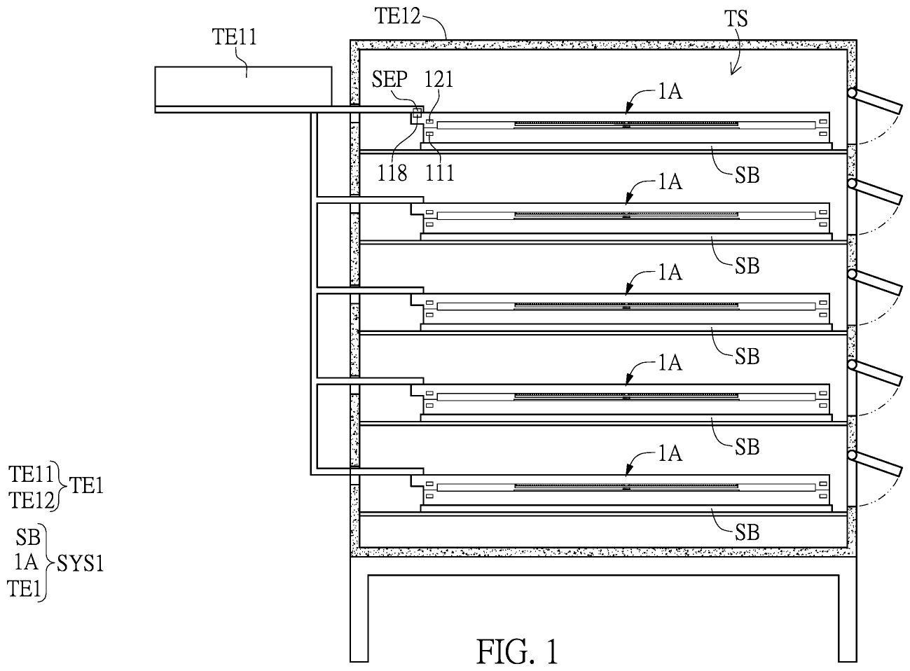

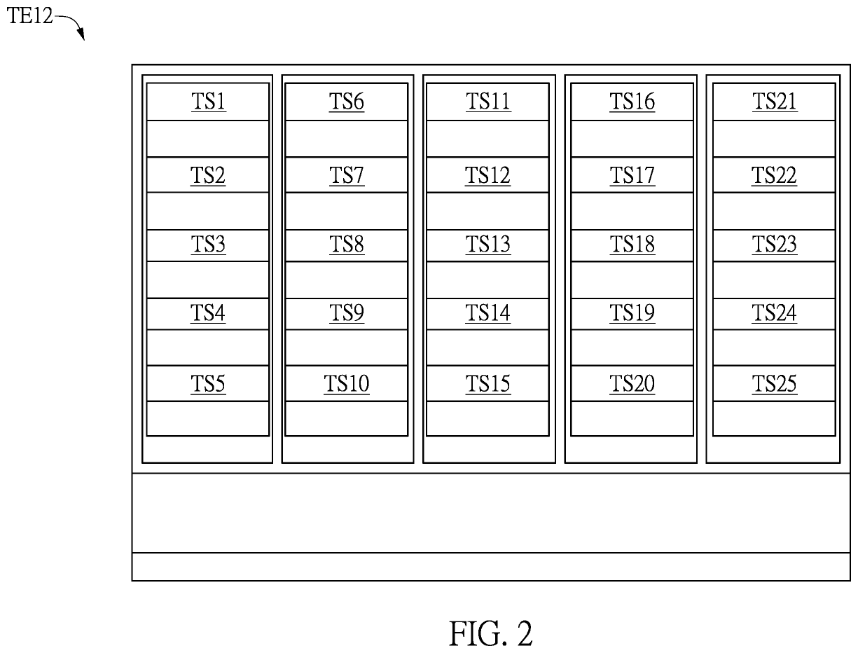

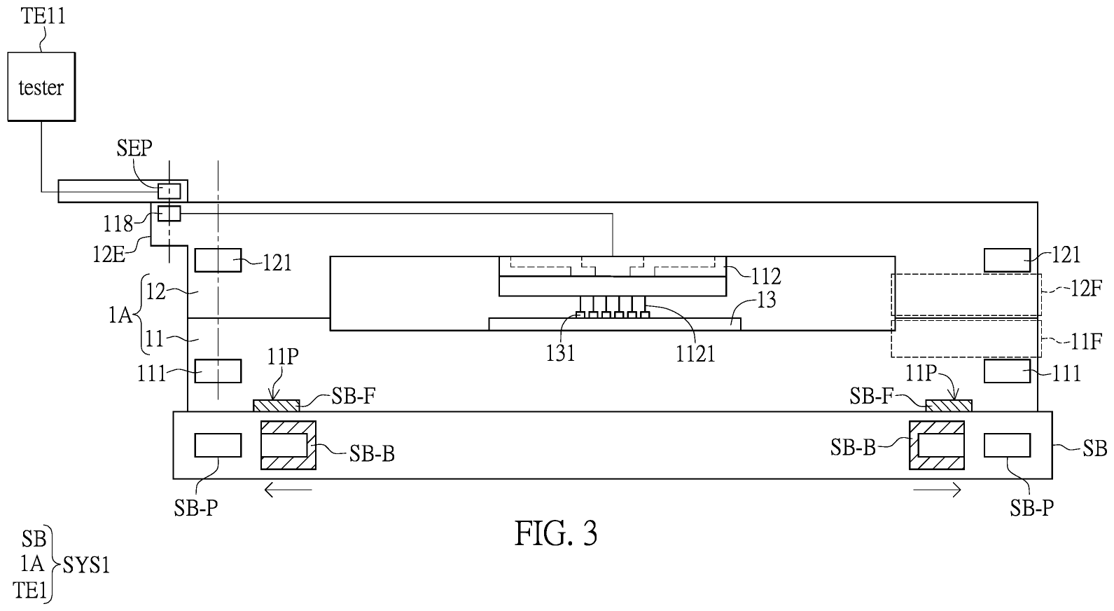

Reference is made to FIG. 1 to FIG. 3, in which FIG. 1 is a schematic view of a test system according to one embodiment of the present disclosure, FIG. 2 is a schematic view of a test cabinet of the embodiment shown in FIG. 1, and FIG. 3 is a schematic view of a wafer test cassette of the embodiment shown in FIG. 1.

In the present embodiment, a test system SYS1 includes at least a wafer test cassette 1A, a carrier SB, and a test equipment TE1. The wafer test cassette 1A is movably disposed on the carrier SB. A probe card 112 is disposed in the wafer test cassette 1A. The probe card 112 includes one or more probes 1121. During a test process, the one or more probes 1121 are correspondingly abutted against pads 131 of a wafer 13, so that the one or more probes 1121 are in electrical contact with the pads of the wafer 13.

Referring to FIG. 1 and FIG. 2, in the present embodiment, the test equipment TE1 includes a tester TE11 and a test cabinet TE12. The test cabinet TE12 has a plurality of test spaces TS (i.e., TS1 to TS25) each is used to accommodate the wafer test cassette 1A. The carrier SB is arranged in a test position of the test space TS.

In the present embodiment, the wafer test cassette 1A includes a first housing 11 and a second housing 12. In certain embodiments, the first housing 11 and the second housing 12 can be tightly coupled to each other by engagement or vacuum. In certain embodiments, the first housing 11 and the second housing 12 can be tightly coupled to each other through a magnetic force, which is described in detail below.

The wafer test cassette 1A is movably disposed on the carrier SB. The wafer test cassette 1A includes a first magnetic member 111 disposed in the first housing 11 or the second housing 12. In the present embodiment, the first magnetic member 111 is disposed in the first housing 11, and the carrier SB includes a second magnetic member SB-P. The wafer test cassette 1A is fixed to the carrier SB through magnetic attraction generated between the first magnetic member 111 and the second magnetic member SB-P. The carrier SB and the wafer test cassette 1A are correspondingly arranged in the test space TS, such that the test process is performed. Each of the first magnetic member 111 and the second magnetic member SB-P can be, but not limited to, a permanent magnet. In certain embodiments, one of the first magnetic member 111 and the second magnetic member SB-P is a magnetically permeable object, and another of the first magnetic member 111 and the second magnetic member is a paramagnetic element, such as an electromagnet and the permanent magnet.

The wafer test cassette 1A has a first electrical contact 118 that can be electrically connected to a second electrical contact SEP of the test cabinet TE12, so that the tester TE11 is electrically connected to the wafer test cassette 1A. In the present embodiment, the first electrical contact 118 is arranged in the second housing 12. In certain embodiments, the first electrical contact 118 is arranged in the first housing 11, but the present is not limited thereto. When the wafer test cassette 1A is arranged in the test space TS, the first electrical contact 118 in the first housing 11 or the second housing 12 is electrically connected to the second electrical contact SEP of the test equipment TE1. In this way, the test equipment TE1 is configured to perform the test process on the wafer 13 in the wafer test cassette 1A. In the present embodiment, the first electrical contact 118 can be arranged on an extension 12E of the second housing 12 to be in electrical contact with the second electrical contact SEP.

In certain embodiments, the tester TE11 is electrically connected to the wafer test cassette 1A at the same time, before, or after the magnetic attraction is generated.

In certain embodiments, the first housing 11 and the second housing 12 are in a tightly coupled state. For example, the first magnetic member 111 is disposed in one of the first housing 11 and the second housing 12, and a third magnetic member 121 is disposed in another of the first housing 11 and the second housing 12. When the first housing 11 and the second housing 12 are close to each other, the first housing 11 and the second housing 12 can be tightly coupled to each other through magnetic attraction generated between the first magnetic member 111 and the third magnetic member 121. In the present embodiment, the wafer test cassette 1A includes two sets of the first magnetic members 111 and the third magnetic members 121. When the first housing 11 and the second housing 12 of the wafer test cassette 1A are close to each other, the first housing 11 and the second housing 12 can be tightly coupled and secured to each other through the magnetic attraction generated between the first magnetic members 111 and the third magnetic members 121.

In certain embodiments, each of the first magnetic member 111 and the third magnetic member 121 can a paramagnetic object, such as the permanent magnet, the non-permanent magnet, and an unmagnetized magnetically permeable object. The unmagnetized magnetically permeable object is, for example, but not limited to, iron, cobalt, or nickel. In the present embodiment, the non-permanent magnet is the electromagnet.

In certain embodiments, the carrier SB includes a magnetic barrier assembly SB-B configured to reduce or eliminate the magnetic attraction between the first magnetic member 111 and the second magnetic member SB-P. When the wafer test cassette 1A is close to the carrier SB, the existence the magnetic attraction as described above may make it difficult to control a force of placing the wafer test cassette 1A on the carrier SB, causing damage to the wafer 13 or the probe card 112 in the wafer test cassette 1A. Therefore, by arranging the magnetic barrier assembly SB-B to eliminate or reduce the magnetic attraction, the wafer test cassette 1A placed on the carrier SB can be further fixed to the carrier SB through the magnetic attraction.

In the present embodiment, as shown in FIG. 3, the magnetic barrier assembly SB-B is a removable shield that blocks the second magnetic member SB-P to eliminate or reduce the magnetic attraction between the second magnetic member SB-P and the first magnetic member 111. After the wafer test cassette 1A is placed on the carrier SB, the magnetic barrier assembly SB-B is separated from the second magnetic member SB-P, and the magnetic attraction is generated or increased between the second magnetic member SB-P and the first magnetic member 111, so that the wafer test cassette 1A can be fixed on the carrier SB. In addition, in certain embodiments, the second magnetic member SB-P is movable, and the second magnetic member SB-P can be the magnetically permeable object, such as iron, nickel, and cobalt, or the permanent magnet. Before the wafer test cassette 1A is placed on the carrier SB, the second magnetic member SB-P is moved to the magnetic barrier assembly SB-B to be shielded by the magnetic barrier assembly SB-B. Accordingly, when the wafer test cassette 1A is placed on the carrier SB, the magnetic attraction is not generated between the first magnetic member 111 and the second magnetic member SB-P. However, after the wafer test cassette 1A is placed on the carrier SB, the second magnetic member SB-P is separated from the magnetic barrier assembly SB-B, and the second magnetic member SB-P is not shielded by the magnetic barrier assembly SB-B, so that the magnetic attraction can be generated between the second magnetic member SB-P and the first magnetic member 111, whereby the wafer test cassette 1A is secured to the carrier SB.

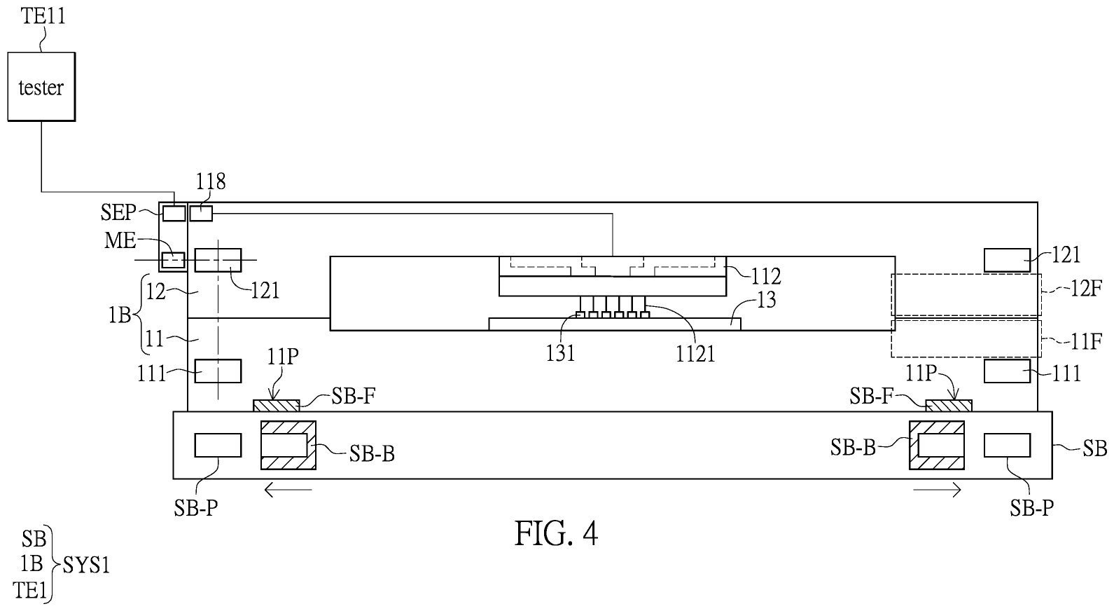

Reference is made to FIG. 4, in which a schematic view of a wafer test cassette 1B according to one embodiment of the present disclosure is shown. In the present embodiment, the first electrical contact 118 of the wafer test cassette 1B is connected to the second electrical contact SEP through the magnetic attraction. For example, the test cabinet TE12 includes a magnetic object ME disposed on one side of the second electrical contact SEP and corresponding to the third magnetic member 121, and the magnetic object ME can be the paramagnetic element or has a polarity opposite to a polarity of the third magnetic member 121. In this way, the first electrical contact 118 can be in electrical contact with the second electrical contact SEP through the magnetic attraction between the magnetic object ME and the third magnetic member 121. However, the present disclosure is not limited thereto. The first electrical contact 118 can also be in electrical contact with the second electrical contact SEP through the magnetic attraction generated in a manner by disposing two magnetic elements that can be attracted to each other respectively on a side of the first electrical contact 118 (i.e., in the wafer test cassette) and a side of the second electrical contact SEP (i.e., in the test cabinet).

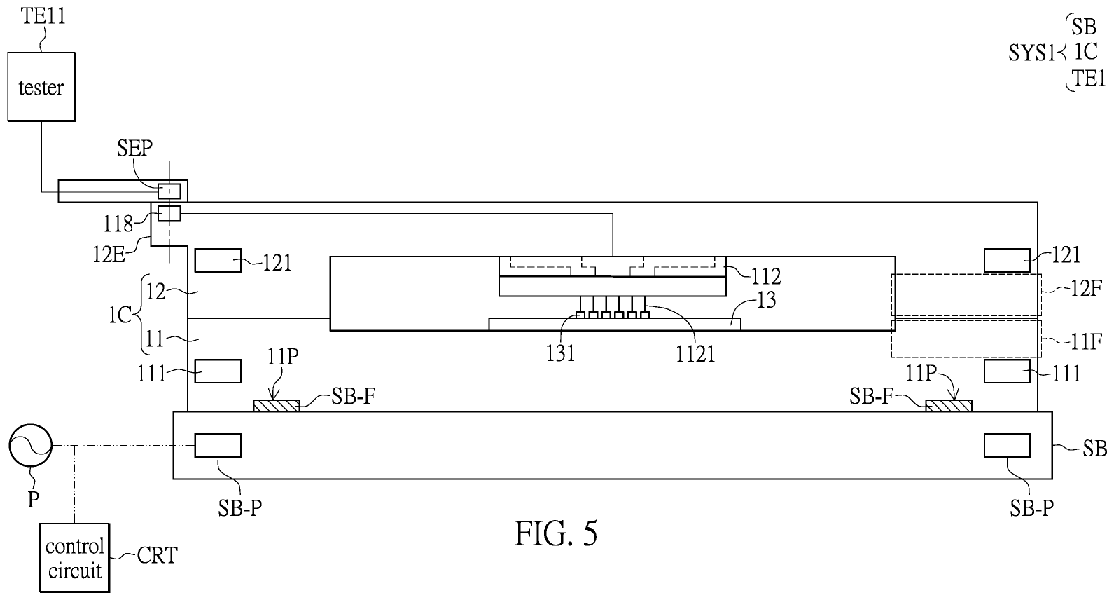

Reference is made to FIG. 5, in which a schematic view of a wafer test cassette 1C according to one embodiment of the present disclosure is shown. In certain embodiments, the second magnetic member SB-P is the electromagnet having a magnetic region, and the magnetic barrier assembly SB-B includes a power supply P and a switch connected to the second magnetic member SB-P (i.e., the electromagnet). After the wafer test cassette 1C is placed on the carrier SB, the switch is turned on and the magnetic force is generated in the magnetic region of the second magnetic member SB-P (i.e., the electromagnet), so that the second magnetic member SB-P (i.e., the electromagnet) is correspondingly attracted to the first magnetic member 111 and the third magnetic member 121, whereby the wafer test cassette 1C is magnetically secured to the carrier SB. The switch can be turned on or turned down through a control circuit CRT.

In certain embodiments, the test cabinet TE12 also includes a slide assembly (not shown in the figures) connected to the carrier SB, and the slide assembly is configured to drive the carrier SB to move toward an interior or an exterior of the test space TS. In certain embodiments, the test system can be manually operated by placing the wafer test cassette on the carrier SB. The arrangement of the slide assembly allows for easier alignment and placement by a human operator (e.g., the wafer test cassette can be precisely aligned with the carrier SB and then placed on the carrier SB). However, the present disclosure is not limiter thereto. In certain embodiments, the test system can also be an automated processing.

Further, in certain embodiments, the carrier SB is the slide assembly, and the slide assembly is, for example, an assembly including two slide carriers (not shown in the figures) respectively disposed on two sides of a bottom of the wafer test cassette. The two slide carriers are configured to support the wafer test cassette and elevate the wafer test cassette in the test space. That is, the wafer test cassette and the bottom (i.e., a bottom wall) of the test space have a spacing therebetween.

Referring to FIG. 3, in certain embodiments, the wafer test cassette 1A has a first positioning structure 11P, the carrier SB has a second positioning structure SB-F corresponding to the first positioning structure 11P, and the second positioning structure SB-F is configured to be engaged to the first positioning structure 11P. As shown in FIG. 3, the first housing 11 has the first positioning structure 11P (e.g., a concave structure such as a groove). The carrier SB has the second positioning structure SB-F projecting upwardly (i.e., a protruding structure similar to a rib). The first positioning structure 11P (i.e., the concave structure) can be engaged to the second positioning structure SB-F (i.e., the protruding structure), so the wafer test cassette 1A can be aligned with the carrier SB. In addition, in the present embodiment, the first housing 11 has a first protruding structure 11F, the second housing 12 has a second protruding structure 12F, and the first protruding structure 11F is arranged corresponding to the second protruding structure 12F. The arrangement of the first protruding structure 11F and the second protruding structure 12F ensures that the first housing 11 and be precisely aligned with the second housing 12 when they are combined. Further, the first housing 11 and the second housing 12 can be further tightly coupled to each other through the magnetic attraction described above.

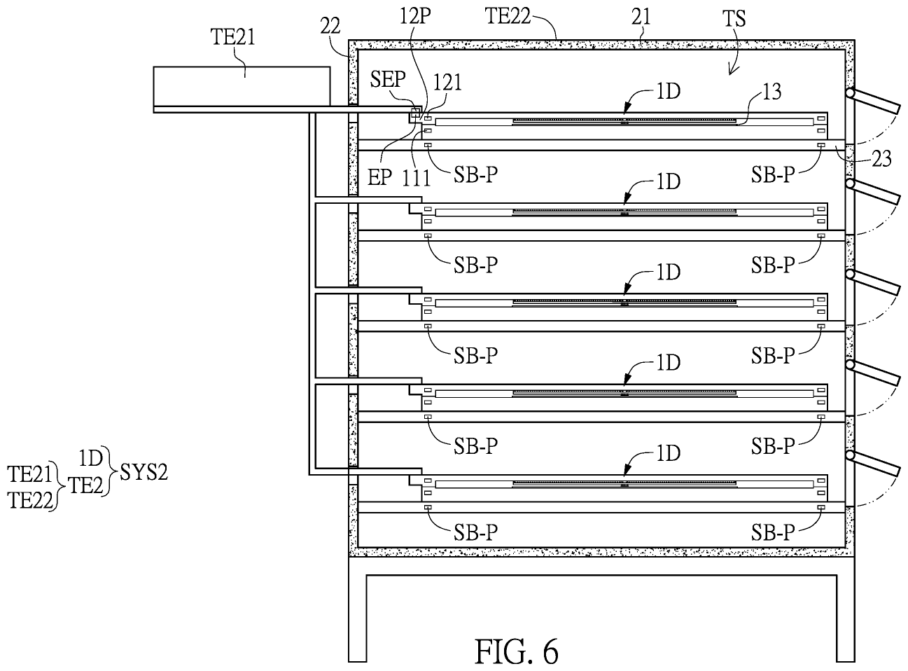

Referring to FIG. 6, the present disclosure also provides a test system, which includes a wafer test cassette 1D and a test equipment TE2. The wafer test cassette 1D includes the first magnetic member 111. The test equipment TE2 includes a tester TE21 and a test cabinet TE22. The test cabinet TE22 has the plurality of test spaces TS used to correspondingly accommodate the wafer test cassettes 1D. The test space TS is defined by a top plate 21, a bottom plate 23, and a side wall 22. The second magnetic member SB-P is disposed in the test space TS, and the second magnetic member SB-P is arranged on the bottom plate 23 or the side wall 22. In the present embodiment, the second magnetic member SB-P is arranged on the bottom plate 23. The wafer test cassette 1D is fixed in the test space TS through the magnetic attraction generated between the first magnetic member 111 and the second magnetic member SB-P, and the wafer test cassette 1D is electrically connected to the tester TE21.

In the present embodiment, the wafer test cassette 1D has the first electrical contact 118 that is able to be electrically connected to the second electrical contact SEP of the test cabinet TE22. In the present embodiment, the first electrical contact 118 is arranged on an extension 12P of the second housing 12. When the wafer test cassette 1D is located in the test space TS, the first electrical contact 118 is electrically connected to the second electrical contact SEP of the test equipment TE2. In this way, the test equipment TE2 is configured to perform a test process on the wafer 13 in the wafer test cassette 1D.

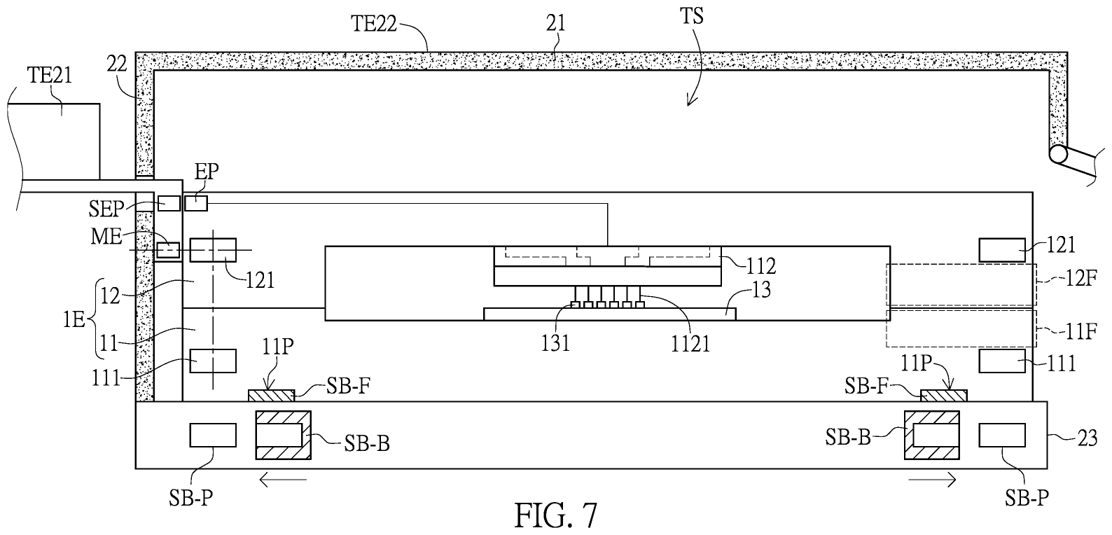

Reference is made to FIG. 7, in which a schematic view of a wafer test cassette 1E according to one embodiment of the present disclosure is shown. In the present embodiment, the first electrical contact 118 of the wafer test cassette 1E is connected to the second electrical contact SEP through the magnetic attraction. For example, the test cabinet TE22 includes the magnetic object ME disposed on the side wall 22, arranged on a side of the second electrical contact SEP, and corresponding to the third magnetic member 121. The magnetic object ME can be the paramagnetic element or have a polarity opposite to the polarity of the third magnetic member 121. In this way, the first electrical contact 118 can be in electrical contact with the second electrical contact SEP through the magnetic attraction between the magnetic object ME and the third magnetic member 121. However, the present disclosure is not limited thereto. Two magnetic elements that can be attracted to each other can also be provided. One of the two magnetic elements can be disposed on the side of the first electrical contact 118 (i.e., in the wafer test cassette), and another of the two magnetic elements can be disposed on the top plate 21, the side wall 22, or the bottom plate 23, and on the side of the second electrical contact SEP. In this way, the first electrical contact 118 can be in electrical contact with the second electrical contact SEP through the mutual magnetic attraction therebetween.

Numbers and positions of the first magnetic member 111, the second magnetic member SB-P, and the third magnetic member can be adjusted according to practical requirements, but the present disclosure is not limited thereto.

### BENEFICIAL EFFECTS OF THE EMBODIMENTS

In conclusion, one of the beneficial effects of the present disclosure is that the test system provided by the present disclosure can effectively improve efficiency of a wafer test process. In addition, the test equipment is connected to the wafer test cassette through a magnetic structure, so that a test environment can be effectively controlled.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A wafer test system, comprising:
a wafer test cassette including a first magnetic member and at least one first electrical contact; and
a test equipment including:
a tester; and
at least one test cabinet including:
a plurality of test spaces;
a plurality of second electrical contacts; and
a plurality of carriers each including a second magnetic member, the carrier being arranged in a test position of the test space;
wherein the test space is used to accommodate the wafer test cassette;
wherein the second electrical contact is configured to be electrically connected to the first electrical contact, so that the tester is electrically connected to the wafer test cassette;
wherein the wafer test cassette is fixed to the carrier through magnetic attraction generated between the first magnetic member and the second magnetic member.

2. The wafer test system according to claim 1, wherein the tester is electrically connected to the wafer test cassette at the same time, before, or after the magnetic attraction is generated.

3. The wafer test system according to claim 1, wherein the carrier or the wafer test cassette includes a magnetic barrier assembly configured to reduce or eliminate the magnetic attraction.

4. The wafer test system according to claim 1, wherein the wafer test cassette has an extension, and the first electrical contact is arranged on the extension.

5. The wafer test system according to claim 1, wherein the first electrical contact is connected to the second electrical contact through the magnetic attraction.

6. The wafer test system according to claim 1, wherein the test cabinet further includes a slide assembly connected to the carrier, and the slide assembly is configured to drive the carrier to move toward an interior or an exterior of the test space.

7. The wafer test system according to claim 1, wherein the carrier is a slide assembly correspondingly disposed on two sides of a bottom of the wafer test cassette and configured to support the wafer test cassette.

8. The wafer test system according to claim 1, wherein the wafer test cassette has at least one first positioning structure, the carrier has at least one second positioning structure corresponding to the at least one first positioning structure, and the at least one second positioning structure is configured to be engaged to the at least one first positioning structure.

9. The wafer test system according to claim 1, wherein the wafer test cassette includes a first housing and a second housing that are tightly coupled to each other.

10. A wafer test system, comprising:
a wafer test cassette including a first magnetic member and at least one first electrical contact; and
a test equipment including:
a tester; and
at least one test cabinet each including a plurality of test spaces and a plurality of second electrical contacts;
wherein the test space is used to accommodate the wafer test cassette, and the test space is defined by a top plate, a bottom plate, and a side wall;
wherein a second magnetic member is disposed in the test space, the second magnetic member is disposed on the bottom plate or the side wall, and the wafer test cassette is fixed in the test space through magnetic attraction generated between the first magnetic member and the second magnetic member; and
wherein the second electrical contact of the test cabinet is configured to be electrical connected to the first electrical contact, so that the wafer test cassette is electrical connected to the tester.

11. The wafer test system according to claim 10, wherein the tester is electrically connected to the wafer test cassette at the same time, before, or after the magnetic attraction is generated.

12. The wafer test system according to claim 10, wherein the wafer test cassette or the test space further includes a magnetic barrier assembly configured to reduce or eliminate the magnetic attraction.

13. The wafer test system according to claim 10, wherein the wafer test cassette has an extension, and the first electrical contact is arranged on the extension.

14. The wafer test system according to claim 10, wherein the first electrical contact is connected to the second electrical contact through the magnetic attraction.

15. The wafer test system according to claim 10, wherein the wafer test cassette has at least one first positioning structure, at least one of the top plate, the bottom plate, and the side wall has at least one second positioning structure corresponding to the at least one first positioning structure, and the at least one second positioning structure is configured to be engaged to the at least one first positioning structure.

16. The wafer test system according to claim 10, wherein the wafer test cassette includes a first housing and a second housing that are tightly coupled to each other.
